(19) United States
(12) Patent Application Publication
(10) Pub. No.: US 2026/0059803 A1
(43) Pub. Date: Feb. 26, 2026

(54) FORKSHEET DEVICE WITH MINIMUM GATE METAL AND GATE EXTENSION

(71) Applicant: International Business Machines Corporation, Armonk, NY (US)

(72) Inventors: Ruilong Xie, Niskayuna, NY (US); Reinaldo Vega, Mahopac, NY (US); Brent Alan Anderson, Jericho, VT (US); Lawrence Alfred Clevenger, Saratoga Springs, NY (US); Albert Manhee Chu, Nashua, NH (US); Nicholas Anthony Lanzillo, Wynantskill, NY (US)

(21) Appl. No.: 18/811,345

(22) Filed: Aug. 21, 2024

(51) Int. Cl. H01L 29/49; H01L 21/28; H01L 29/06; H01L 29/423; H01L 29/66; H01L 29/775; H01L 29/786

(52) U.S. Cl. CPC H10D 30/6739; H01L 21/28088; H10D 30/014; H10D 30/43; H10D 30/6735; H10D 30/6757; H10D 62/121; H10D 64/017

(57) ABSTRACT

According to an embodiment of the present invention, a semiconductor device includes a substrate. A plurality of nanosheets are located parallel to the substrate. A first dielectric bar extends upwards from the substrate through the plurality of nanosheets. The plurality of nanosheets extend laterally from sidewalls of the first dielectric bar. A high-k dielectric metal on a frontside surface and a backside surface of each nanosheet in the plurality of nanosheets and on the sidewalls of the first dielectric bar. A work function metal on a frontside surface, a backside surface, and exposed sidewalls of the high-k dielectric metal. A conductive metal fill between the work function metal. The conductive metal fill connecting to a sidewall of the work function metal.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to an embodiment of the present invention, a semiconductor device includes a substrate. A plurality of nanosheets are located parallel to the substrate. A first dielectric bar extends upwards from the substrate through the plurality of nanosheets. The plurality of nanosheets extend laterally from sidewalls of the first dielectric bar. A high-k dielectric metal on a frontside surface and a backside surface of each nanosheet in the plurality of nanosheets and on the sidewalls of the first dielectric bar. A work function metal on a frontside surface, a backside surface, and exposed sidewalls of the high-k dielectric metal. A conductive metal fill between the work function metal. The conductive metal fill connecting to a sidewall of the work function metal.

According to an embodiment of the present invention, a semiconductor device includes a substrate. A plurality of nanosheets are located parallel to the substrate. A first dielectric bar extends upwards from the substrate through the plurality of nanosheets. The plurality of nanosheets extend laterally from sidewalls of the first dielectric bar. A high-k dielectric metal on a frontside surface and a backside surface of each nanosheet in the plurality of nanosheets and on the sidewalls of the first dielectric bar. A work function metal on a frontside surface, a backside surface, and exposed sidewalls of the high-k dielectric metal. A conductive metal fill between the work function metal. The conductive metal fill connecting to a sidewall of the work function metal. A gate contact on a frontside surface of the first dielectric bar.

According to an embodiment of the present invention, a semiconductor device includes a substrate. A plurality of nanosheets are located parallel to the substrate. A first dielectric bar extends upwards from the substrate through the plurality of nanosheets. The plurality of nanosheets extend laterally from sidewalls of the first dielectric bar. A high-k dielectric metal on a frontside surface and a backside surface of each nanosheet in the plurality of nanosheets and on the sidewalls of the first dielectric bar. A work function metal on a frontside surface, a backside surface, and exposed sidewalls of the high-k dielectric metal. A conductive metal fill between the work function metal. The conductive metal fill connecting to a sidewall of the work function metal. A gate contact on a frontside surface of the first dielectric bar. A via connected to the frontside surface of the gate contact.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2 and 3 illustrate cross sections X and Y, respectively, of the plurality of nanodevices after nanosheet formation, sacrificial layer formation, and gate hard mask formation, according to the embodiment of the present invention.

FIGS. 4 and 5 illustrate cross sections X and Y, respectively, of the plurality of nanodevices after the formation of a plurality of trenches, according to the embodiment of the present invention.

FIGS. 6 and 7 illustrate cross sections X and Y, respectively, of the plurality of nanodevices after dielectric bar formation, according to the embodiment of the present invention.

FIGS. 8 and 9 illustrate cross sections X and Y, respectively, of the plurality of nanodevices after shallow trench isolation (STI) region formation and gate hard mask removal, according to the embodiment of the present invention.

FIGS. 10 and 11 illustrate cross sections X and Y, respectively, of the plurality of nanodevices after dummy gate formation, removal of a fifth sacrificial layer, gate spacer and top dielectric bar formation, nanosheet recessing, inner spacer formation, source/drain (S/D) formation and interlayer dielectric (ILD) deposition, according to the embodiment of the present invention.

FIGS. 12 and 13 illustrate cross sections X and Y, respectively, of the plurality of nanodevices after dummy gate removal and sacrificial layer removal, according to the embodiment of the present invention.

FIGS. 14 and 15 illustrate cross sections X and Y, respectively, of the plurality of nanodevices after high-k dielectric metal deposition, according to the embodiment of the present invention.

FIGS. 16 and 17 illustrate cross sections X and Y, respectively, of the plurality of nanodevices after work function metal (WFM) formation, according to the embodiment of the present invention.

FIGS. 18 and 19 illustrate cross sections X and Y, respectively, of the plurality of nanodevices after conductive metal fill formation and a first chemical-mechanical planarization (CMP), according to the embodiment of the present invention.

FIGS. 20 and 21 illustrate cross sections X and Y, respectively, of the plurality of nanodevices after conductive metal fill recessing and self-aligned contact (SAC cap) formation, according to the embodiment of the present invention.

FIGS. 22 and 23 illustrate cross sections X and Y, respectively, of the plurality of nanodevices after gate cut formation, according to the embodiment of the present invention.

FIGS. 24 and 25 illustrate cross sections X and Y, respectively, of the plurality of nanodevices after selective conductive metal fill recessing, according to the embodiment of the present invention.

FIGS. 26 and 27 illustrate cross sections X and Y, respectively, of the plurality of nanodevices after dielectric fill deposition and a second CMP, according to the embodiment of the present invention.

FIGS. 28 and 29 illustrate cross sections X and Y, respectively, of the plurality of nanodevices after a first option for middle-of-line (MOL) formation, according to the embodiment of the present invention.

FIGS. 30 and 31 illustrate cross sections X and Y, respectively, of the plurality of nanodevices after a second option for middle-of-line (MOL) formation, according to the embodiment of the present invention.

FIGS. 32 and 33 illustrate cross sections X and Y, respectively, of the plurality of nanodevices after less-selective conductive metal fill recessing, according to the embodiment of the present invention.

FIGS. 34 and 35 illustrate cross sections X and Y, respectively, of the plurality of nanodevices after middle-of-line (MOL) formation with less-selective W recessing, according to the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection. ”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about”means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

The traditional process for creating forksheet transistor structures involves creating ridges in a substrate and backfilling with a dielectric to create a backbone. Proper proportionality of gate metal and gate extensions is required to adequately create forksheet transistor structure. However, fabrication of transistors may result in inopportune parasitic capacitance, which may result in degraded performance and reliability concerns.

By creating a backbone pattern, removing sacrificial nanosheets, forming a work function metal (WFM) that wraps around three sides of the remaining nanosheets, and forming a gate metal in the space between the WFM, parasitic capacitance may be minimized.

Additionally, after W fill formation and gate formation, an etched recess into W fill between the gate metal allows for a minimum possible gate metal for nanosheet transistors and greatly benefits edge capacitance. The present invention does not require that all advantages need to be incorporated into every embodiment of the invention.

The present invention is directed to forming a forksheet transistor structure with minimum gate metal and gate extension to minimize parasitic capacitance. The forksheet structure is formed through a multistage processing, where the first stage forms a modified nanosheet stack. The second stage forms a first plurality of trenches in the modified nanosheet stack through backbone patterning. The third stage grows a first dielectric to fill the first plurality of trenches generated through the backbone patterning and forms a second plurality of trenches through an isotropic etch back process. The fourth stage forms a forksheet structure and removes sacrificial layer. The fifth stage forms a high-k dielectric around the forksheet structure. The sixth stage forms a work function metal (WFM) around the high-k dielectric. The seventh stage forms a gate around the forksheet structure. The eighth stage forms a SAC cap on the frontside of the forksheet structure, the dielectric, and a conductive metal fill. The ninth stage forms a gate cut through the SAC cap and the conductive metal fill. The tenth stage selectively recesses the conductive metal fill around the WFM. The eleventh stage forms a dielectric fill in the gate cut and recesses. The twelfth stage performs middle-of-line (MOL) formation through the ILD and the first dielectric.

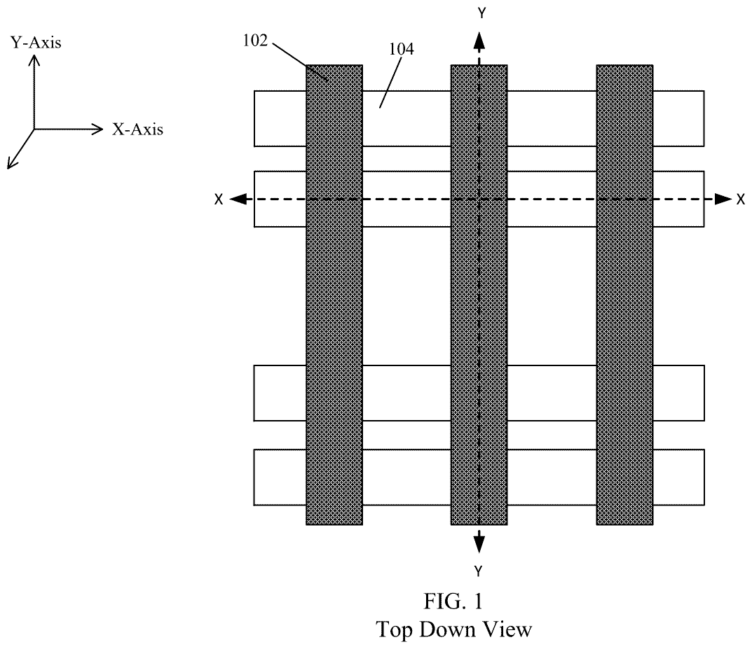

FIG. 1 illustrates a top-down view of a plurality of nanodevices ND1, ND2, ND3, ND4, in accordance with the embodiment of the present invention. The adjacent and parallel devices along an x-axis include a first nanodevice ND1, a second nanodevice ND2, a third nanodevice ND3, and a fourth nanodevice ND4 including a plurality of transistors. Cross-section X is a cross section perpendicular to the gates along the horizontal axis of the third nanodevice ND3. Cross-section Y₁ is a cross section parallel to the gates in the gate region 102 across the plurality of nanodevices ND1, ND2, ND3, ND4. Cross-section Y₂ is a cross section parallel to the gates in the source/drain region 104 across the plurality of nanodevices ND1, ND2, ND3, ND4. Dashed box 103 illustrates the cell boundary region between the second nanodevice ND2 and the third nanodevice ND3. It may be appreciated that the embodiment of the present invention is not limited to nanodevices ND1, ND2, ND3, ND4 and that other devices including, but not limited to, nanosheet transistors, FinFET, nanowire, and a planar device may also be used.

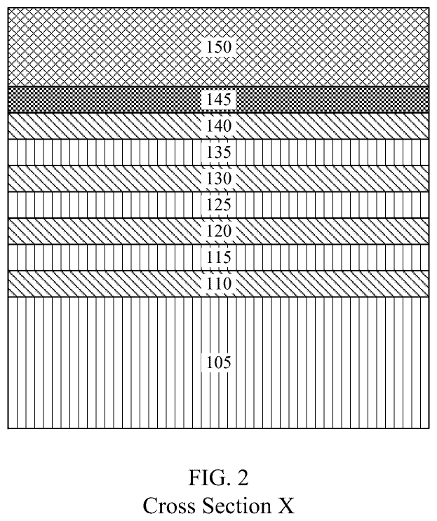

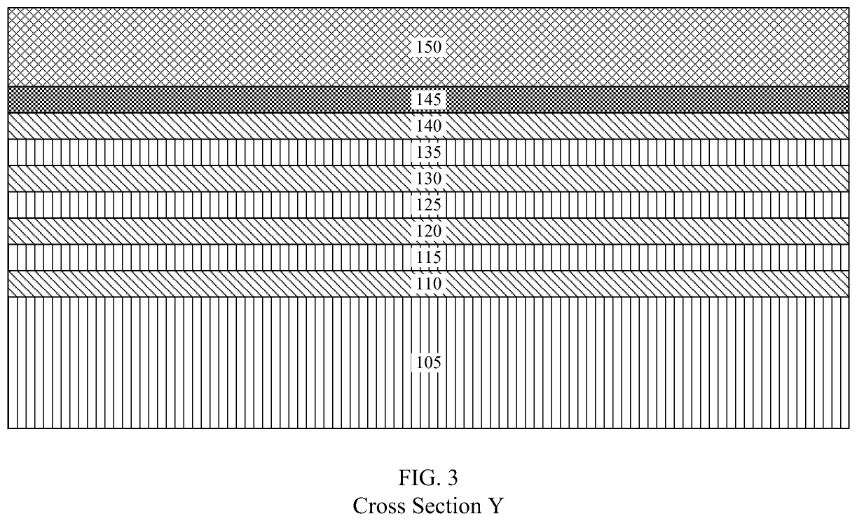

FIGS. 2 and 3 illustrate cross sections X and Y, respectively, of the plurality of nanodevices ND1, ND2, ND3, ND4 after nanosheet 115, 125, 135 formation, sacrificial layer 110, 120, 130, 140, 145 formation, and gate hard mask 150 formation, according to the embodiment of the present invention. The modified nanosheet stack may include various layers of semiconductor materials, such as a substrate 105, the plurality of nanosheets 115, 125, 135, and the plurality of sacrificial layers 110, 120, 130, 140, 145. The substrate 105, the plurality of nanosheets 115, 125, 135, and the plurality of sacrificial layers 110, 120, 130, 140, 145 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In the embodiment, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire substrate 105 may also be comprised of an amorphous, polycrystalline, or monocrystalline. The substrate 105 may be doped, undoped or contain doped regions and undoped regions therein. For example, the substrate 105, the first nanosheet 115, the second nanosheet 125, and the third nanosheet 135 may be comprised of silicon, whereas the first sacrificial layer 110, the second sacrificial layer 120, the third sacrificial layer 130, and the fourth sacrificial 140 may be comprises of SiGe, where Ge is about 25%, and the fifth sacrificial layer 145 may be comprised of SiGe, where Ge is about 55%.

The first sacrificial layer 110 is formed directly atop the substrate 105. The first nanosheet 115 is formed directly atop the first sacrificial layer 110. The second sacrificial layer 120 is formed directly atop the first nanosheet 115. The second nanosheet 125 is formed directly atop the second sacrificial layer 120. The third sacrificial layer 130 is formed directly atop the second nanosheet 125. The third nanosheet 135 is formed directly atop the third sacrificial layer 130. The fourth sacrificial layer 140 is formed directly atop the third nanosheet 135. The fifth sacrificial layer 145 is formed directly atop the fourth sacrificial layer 140. The number of layers described above are not intended to be limiting, and it may be appreciated that in the embodiment of the present invention the number of layers may vary.

A gate hard mask 150 is formed directly atop the underlying fifth sacrificial layer 145. The gate hard mask 150 may be a film that is more resistant to etching than conventional photoresist.

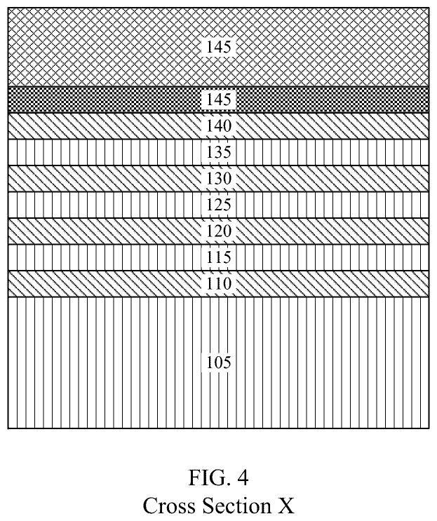

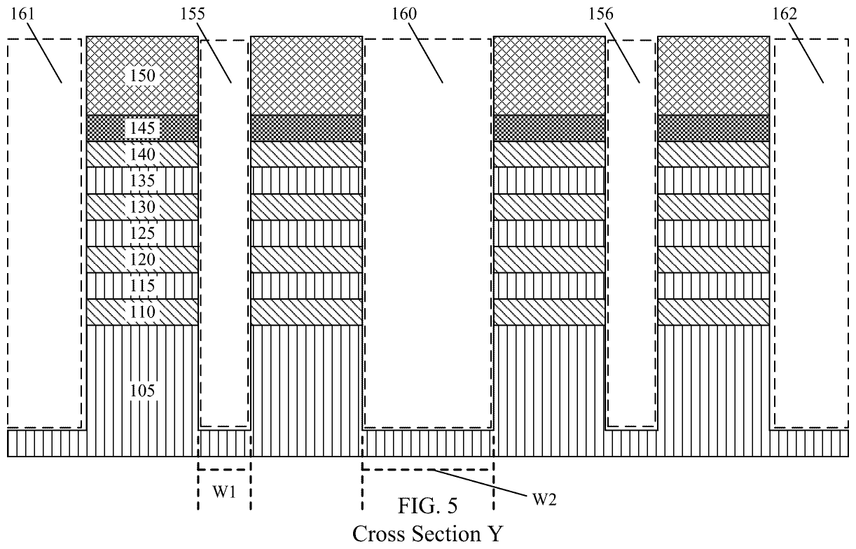

FIGS. 4 and 5 illustrate cross sections X and Y, respectively, of the plurality of nanodevices ND1, ND2, ND3, ND4 after the formation of a plurality of trenches 155, 156, 160-162, according to the embodiment of the present invention. In FIG. 4, a portion of the substrate 105, the plurality of nanosheets 115, 125, 135, the plurality of sacrificial layers 110, 120, 130, 140, 145, and gate hard mask 150 are etched to form a first plurality of trenches 155, 156 and a second plurality of trenches 160-162 between the first plurality of trenches 155, 156. The first plurality of trenches 155, 156 have a first width W1 along the y-axis and the second plurality of trenches 160-162 have a second width W2 along the y-axis.

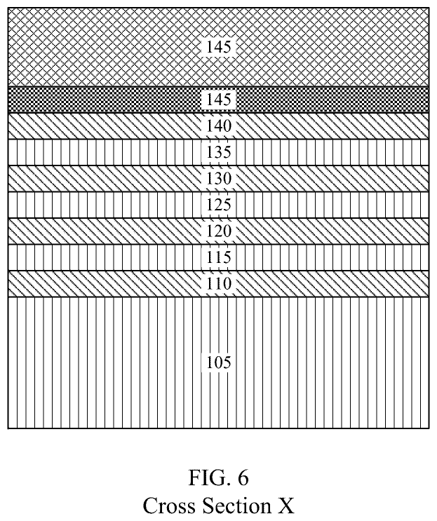

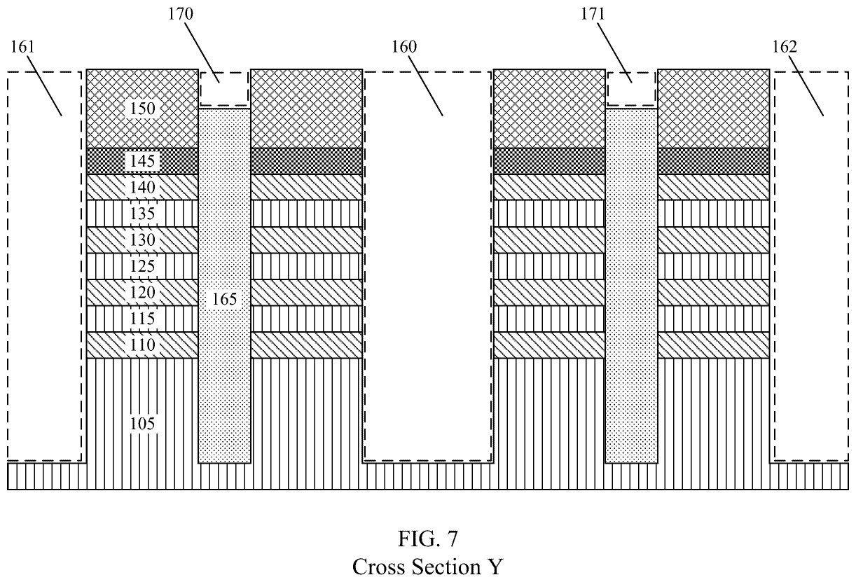

FIGS. 6 and 7 illustrate cross sections X and Y, respectively, of the plurality of nanodevices ND1, ND2, ND3, ND4 after dielectric bar 165 formation, according to the embodiment of the present invention. In FIG. 7, a dielectric material is deposited in the first plurality of trenches 155,156 and etched back to create the first plurality of dielectric bars 165, up to a portion of the gate hard mask 150, and a third plurality of trenches 170, 171.

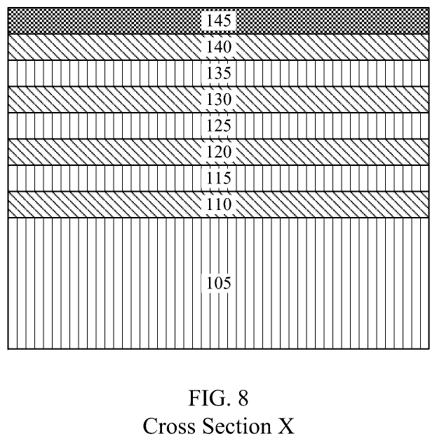

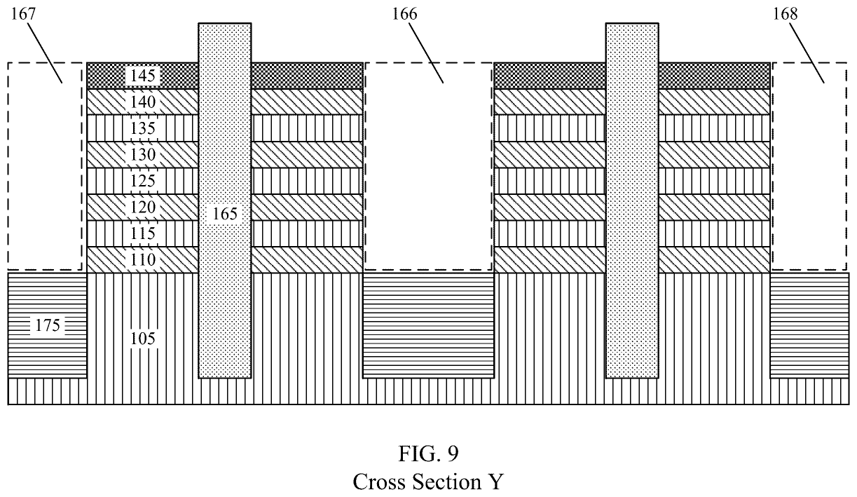

FIGS. 8 and 9 illustrate cross sections X and Y, respectively, of the plurality of nanodevices ND1, ND2, ND3, ND4 after shallow trench isolation (STI) region 175 formation and gate hard mask 150 removal, according to the embodiment of the present invention. In FIG. 9, the STI region 175 is then formed within a fourth plurality of trenches 166-168 so that the STI region 175 is flush with the bottom of the first sacrificial layer 110. The STI region 175 relates to a structure that separates neighboring transistors or memory cells. The STI region 175 is formed by dielectric filling, CMP, and dielectric recess.

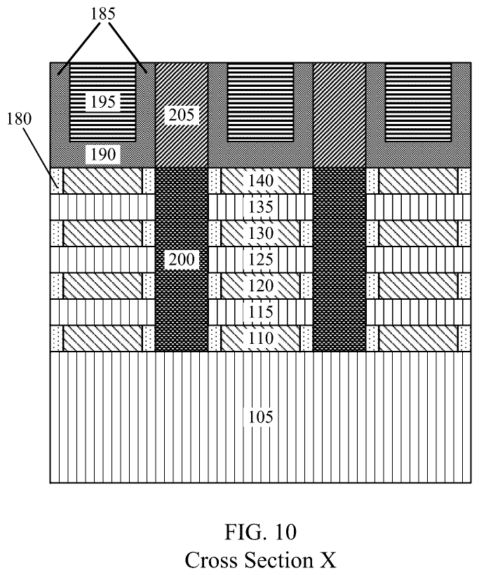

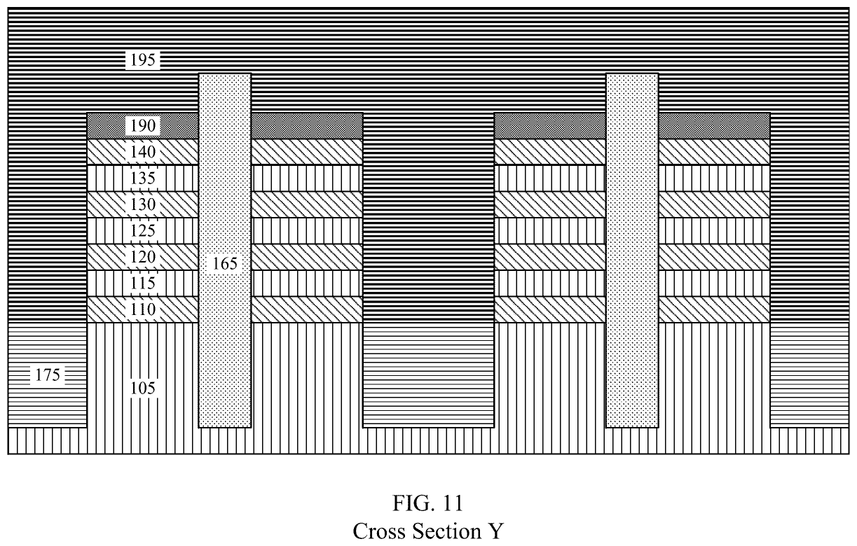

FIGS. 10 and 11 illustrate cross sections X and Y, respectively, of the plurality of nanodevices ND1, ND2, ND3, ND4 after dummy gate 195 formation, removal of a fifth sacrificial layer 145, gate spacer 185 and top dielectric bar 190 formation, nanosheet recessing (not shown), inner spacer 180 formation, source/drain (S/D) 195 formation and interlayer dielectric (ILD) 205 deposition, according to the embodiment of the present invention. During dummy gate 195 formation, the fifth sacrificial layer 145 is selectively removed and replaced with a gate spacer 185 and top dielectric bar 190 during dummy gate 195 deposition. In FIG. 10, the gate spacer 185 and top dielectric bar 190 are formed on upper sidewalls of the plurality of dielectric bars 165. In FIG. 11, the top dielectric bar 190 is formed on upper sidewalls of the plurality of dielectric bars 165. The gate spacer 185 and the top dielectric bar 185 form a contiguous unitary structure made of the same or a different dielectric material. The dielectric used in the gate spacer 185 and top dielectric bar 190 is any non-conductive material used to insulate conductive components in a device.

Then, the nanosheet stack at the S/D region 104 is recessed, followed by indentation of sacrificial layers 110, 120, 130, 140 and inner spacer 180 formation. Then, a fifth plurality of trenches (not shown) are formed through nanosheet recessing to the top of substrate 105. Then, the plurality of source/drains 200 are epitaxially grown in the fifth plurality of trenches over exposed sidewalls of the plurality of nanosheets 115, 125, 135 followed by ILD 205 deposition. The plurality of source/drains 200 are formed directly atop the substrate 105.

The plurality of source/drains 200 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In FIG. 10, the ILD 205 is formed directly atop plurality of source/drains 200, and surrounds one side of the gate spacer 185 and top dielectric bar 190.

In FIG. 10, the dummy gate material is deposited in a sixth plurality of trenches (not shown) created by the removal of the material comprising the gate spacer 185 and top dielectric bar 190 to form the dummy gate 195. In FIG. 11, the dummy gate material is deposited in the sixth plurality of trenches 166-168 (FIG. 9), and directly atop the STI region 175, the top dielectric bar 190, and the plurality of dielectric bars 165 to form the dummy gate 195. The dummy gate 195 can be comprised of, for example, a gate dielectric liner, such as a high-k dielectric like HfO2, ZrO2, HfLaOx, etc., and work function layers, such as TiN, TiAlC, TiC, etc., and conductive metal fills, like W, TaN, Ru, Al, and TiAlC.

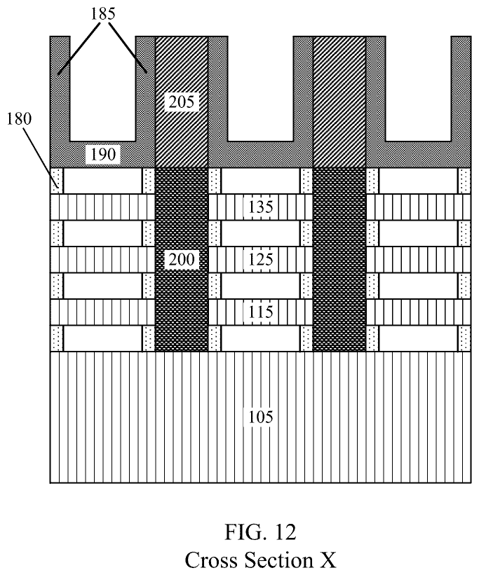

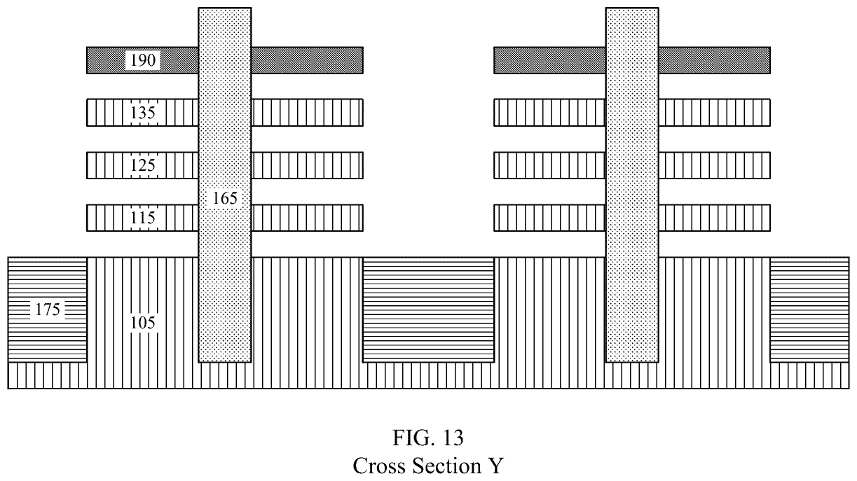

FIGS. 12 and 13 illustrate cross sections X and Y, respectively, of the plurality of nanodevices ND1, ND2, ND3, ND4 after dummy gate 195 removal and sacrificial layer 110, 120, 130, 140 removal, according to the embodiment of the present invention. The dummy gate 195 and the plurality of sacrificial layers 110, 120, 130, 140 are removed to expose the gate spacer 185 and top dielectric bar 190, the inner spacers 180, the plurality of nanosheets 115, 125, 135, the substrate 105, the plurality of dielectric bars 165, and the STI region 175.

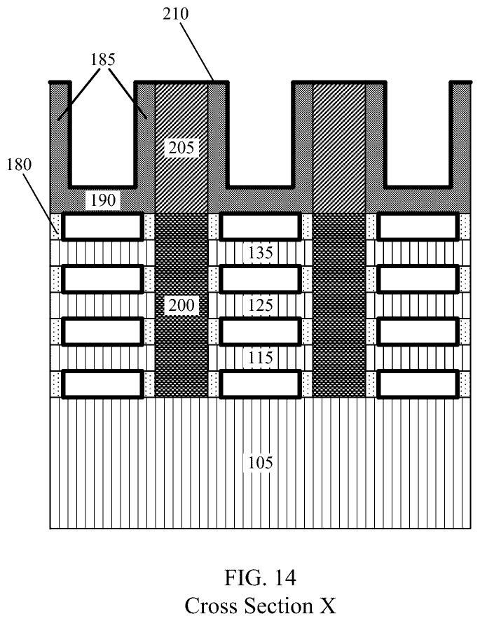

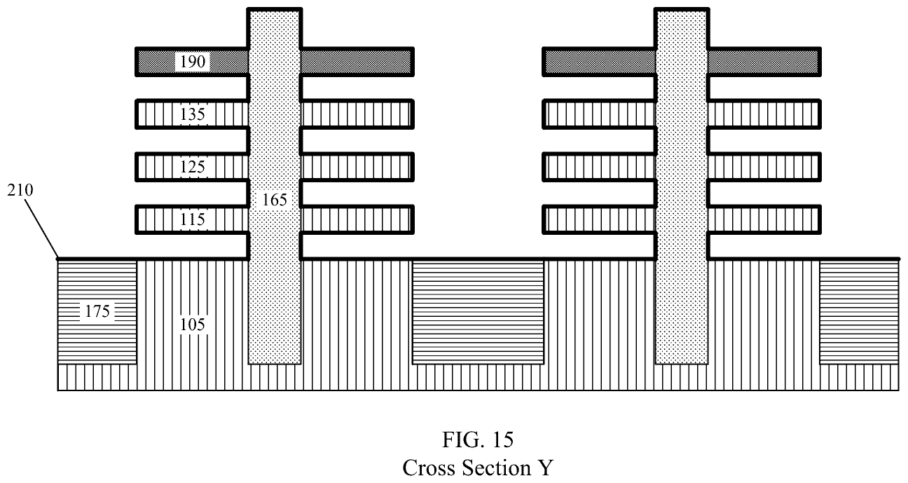

FIGS. 14 and 15 illustrate cross sections X and Y, respectively, of the plurality of nanodevices ND1, ND2, ND3, ND4 after high-k dielectric metal 210 deposition, according to the embodiment of the present invention. In FIG. 14, the high-k dielectric metal 210 is formed on exposed surfaces of the gate spacer 185 and top dielectric bar 190, the inner spacers 180, the plurality of nanosheets 115, 125, 135, the substrate 105, and ILD 205. In FIG. 15, the high-k dielectric metal 210 is formed on exposed surfaces of the top dielectric bar 190, the plurality of nanosheets 115, 125, 135, the substrate 105, the plurality of dielectric bars 165, and the STI region 175. The high-k dielectric metal 210 is an insulating material with a high dielectric constant (k) value (e.g., HfO2, ZrO2, HfLaOx, etc.) that is used in a transistor gate stack to lower transistor leakage.

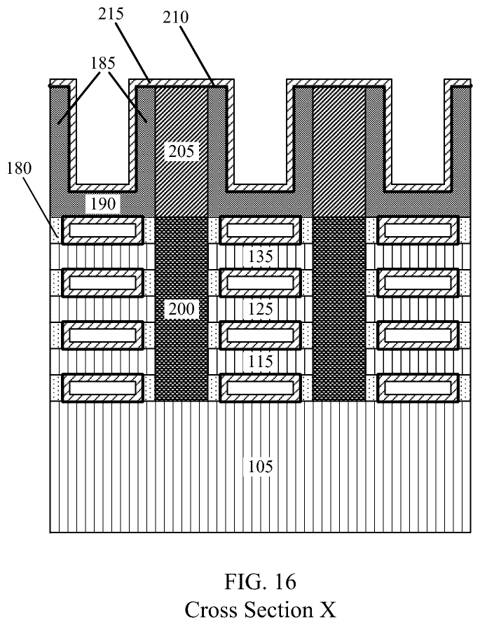

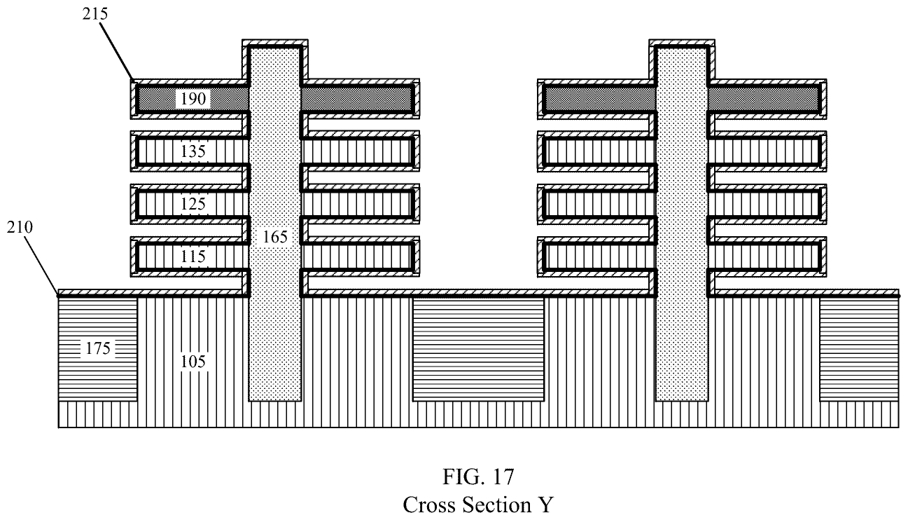

FIGS. 16 and 17 illustrate cross sections X and Y, respectively, of the plurality of nanodevices ND1, ND2, ND3, ND4 after work function metal (WFM) 215 formation, according to the embodiment of the present invention. The WFM 215 is formed directly atop and along exposed sidewalls of the high-k dielectric metal 210. The WFM 215 is a material used in the gate stack of transistors to control the threshold voltage (Vₜ) of the device. The work function is the minimum energy required to remove an electron from the material to a vacuum. By selecting appropriate WFMs 215, transistor electrical properties may be fine tuned to ensure operational efficiency and reliability.

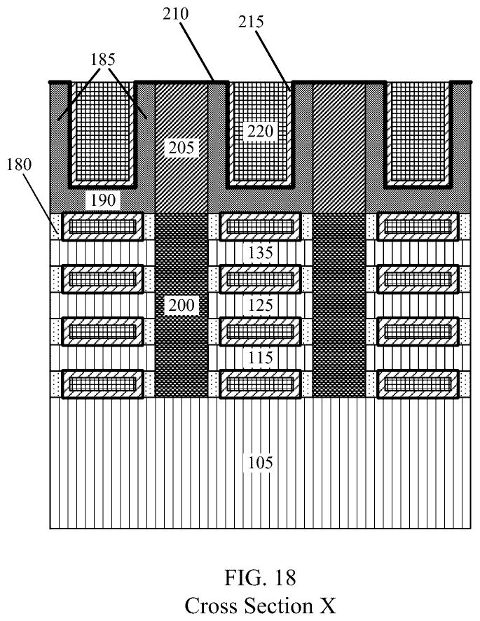

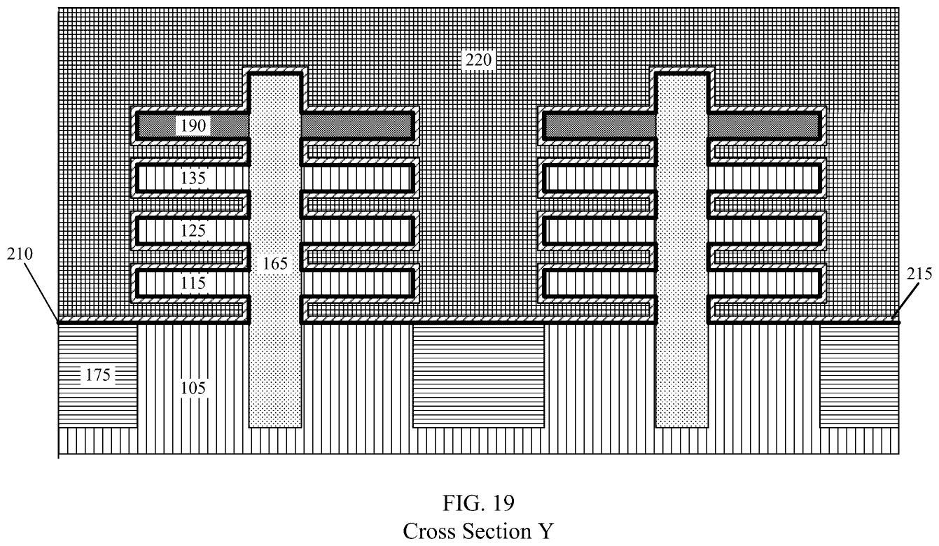

FIGS. 18 and 19 illustrate cross sections X and Y, respectively, of the plurality of nanodevices ND1, ND2, ND3, ND4 after conductive metal fill 220 formation and a first CMP, according to the embodiment of the present invention. The conductive metal fill 220 is a tungsten, or tungsten alloy, fill material. The conductive metal fill 220 is formed directly atop and along exposed sidewalls of the WFM 215. A portion of the conductive metal fill 220 is selectively removed by, for example, the first CMP.

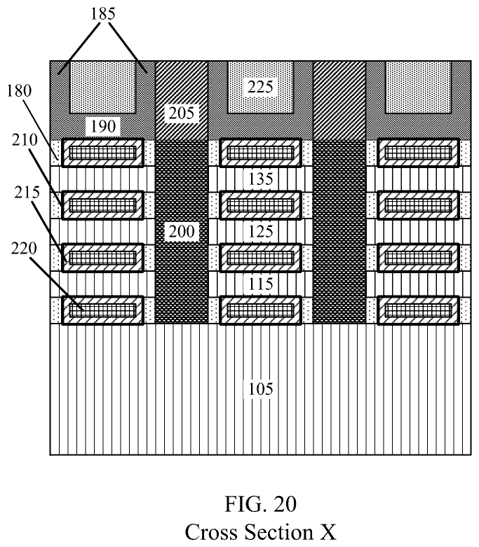

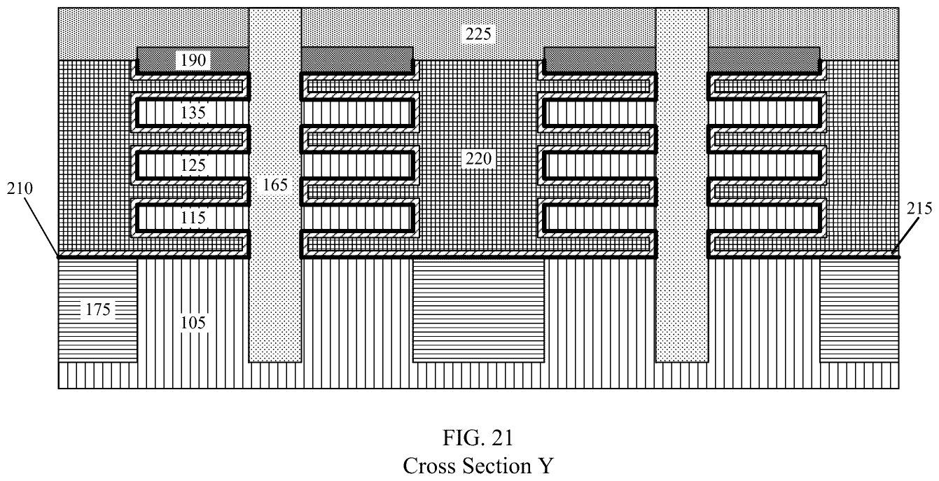

FIGS. 20 and 21 illustrate cross sections X and Y, respectively, of the plurality of nanodevices ND1, ND2, ND3, ND4 after conductive metal fill 220 recessing and self-aligned contact (SAC cap) 225 formation, according to the embodiment of the present invention. In FIG. 20, HKMG recessing is performed to remove the conductive metal fill 220, WFM 215, and high-k dielectric metal 210 formed atop the gate spacer 185, top dielectric bar 185, and ILD 200 and a portion of the gate spacer 185, top dielectric bar 190, and ILD 200. Then, SAC cap 225 is formed atop and along exposed sidewalls of the gate spacer 185 and the top dielectric bar 190 to the top of ILD 200. In FIG. 21, HKMG recessing is performed to remove the conductive metal fill 220, WFM 215, and the high-k dielectric metal 210 formed atop the plurality of dielectric bars 165, the gate spacer 185, and the top dielectric bar 190 and along a portion of the sidewalls of the gate spacer 185 and the top dielectric bar 190. Then, SAC cap 225 is formed in the space formed by HKMG recessing (not shown) atop the gate spacer 185 and the top dielectric bar 190 to the plurality of dielectric bars 165 and along the exposed sidewalls of the top dielectric bar 190.

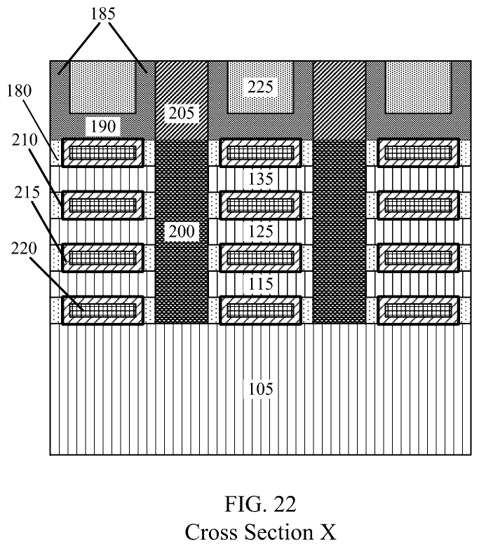

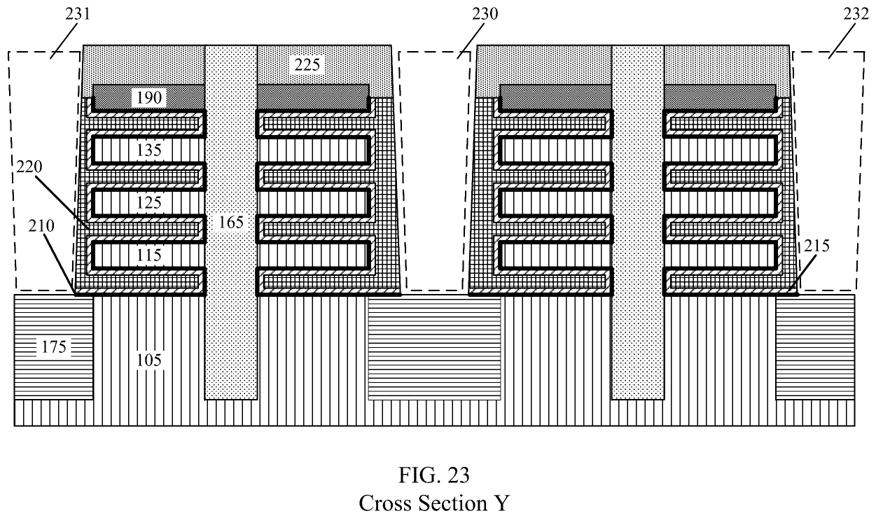

FIGS. 22 and 23 illustrate cross sections X and Y, respectively, of the plurality of nanodevices ND1, ND2, ND3, ND4 after gate cut 230-232 formation, according to the embodiment of the present invention. The gate cuts 230-232 are formed between the plurality of dielectric bars 165 and proceed through the SAC cap 225, the conductive metal fill 220, the WFM 215, and the high-k dielectric metal 210.

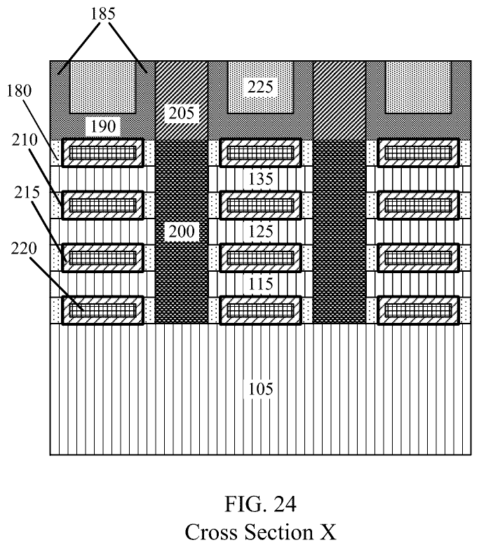

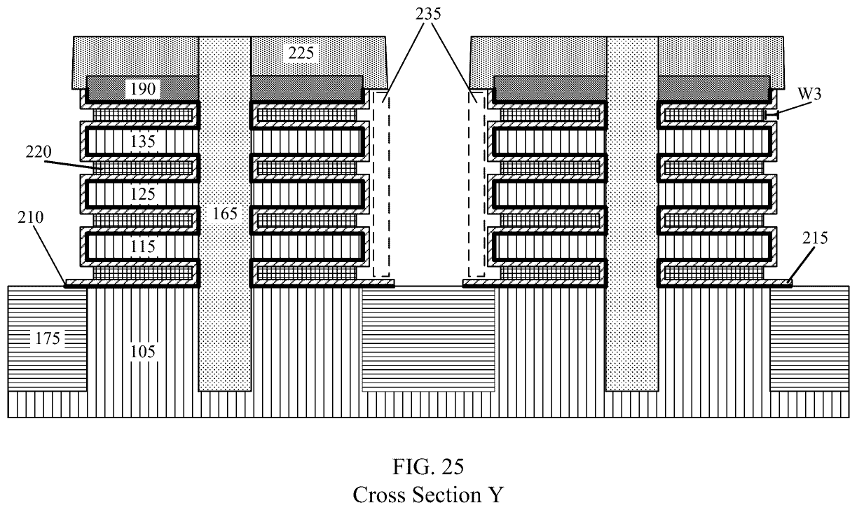

FIGS. 24 and 25 illustrate cross sections X and Y, respectively, of the plurality of nanodevices ND1, ND2, ND3, ND4 after selective conductive metal fill 220 recessing, according to the embodiment of the present invention. In FIG. 25, a plurality of recesses 235 are formed directly atop the WFM 215 to the backside of the SAC cap 225 and, laterally, through a portion of the conductive metal fill 220 until sidewalls of the WFM 215 are exposed. Then, the plurality of recesses 235 are further extended through a portion of the conductive metal fill 220 for a width W3.

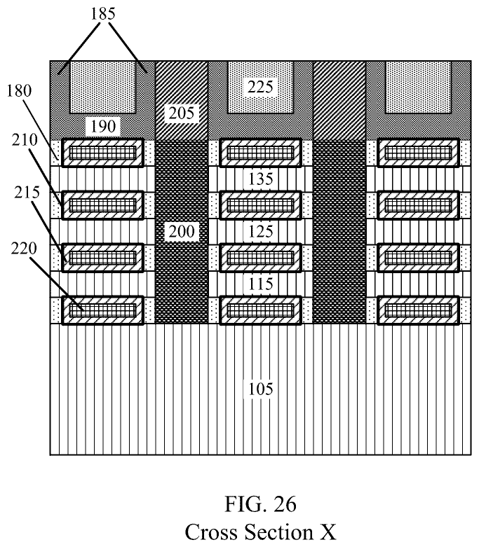

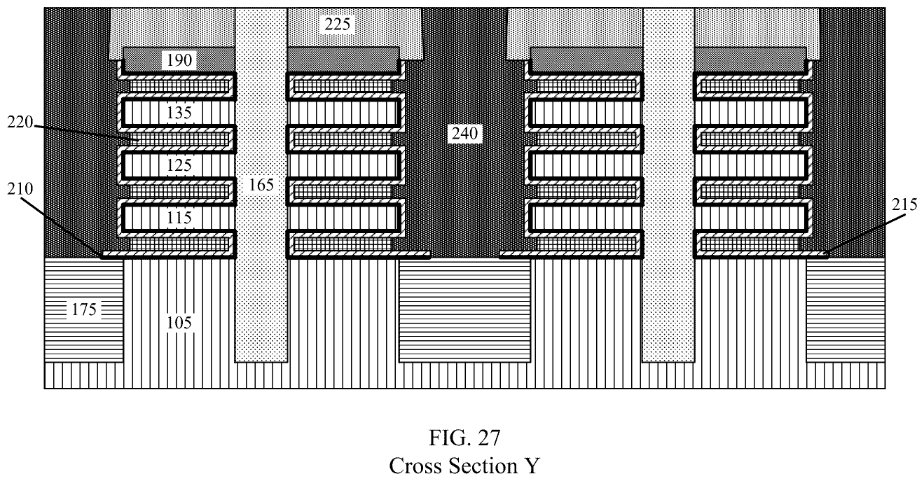

FIGS. 26 and 27 illustrate cross sections X and Y, respectively, of the plurality of nanodevices ND1, ND2, ND3, ND4 after dielectric fill 240 deposition and a second CMP, according to the embodiment of the present invention. In FIG. 27, a dielectric material is deposited in the gate cuts 230-232 and the plurality of recesses 235 to form the dielectric fill 240.

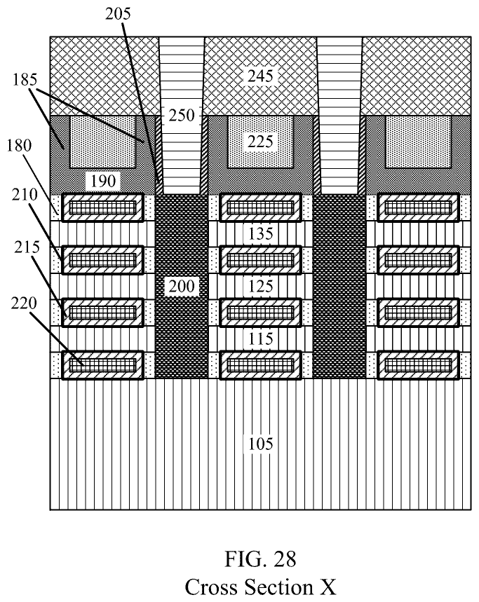

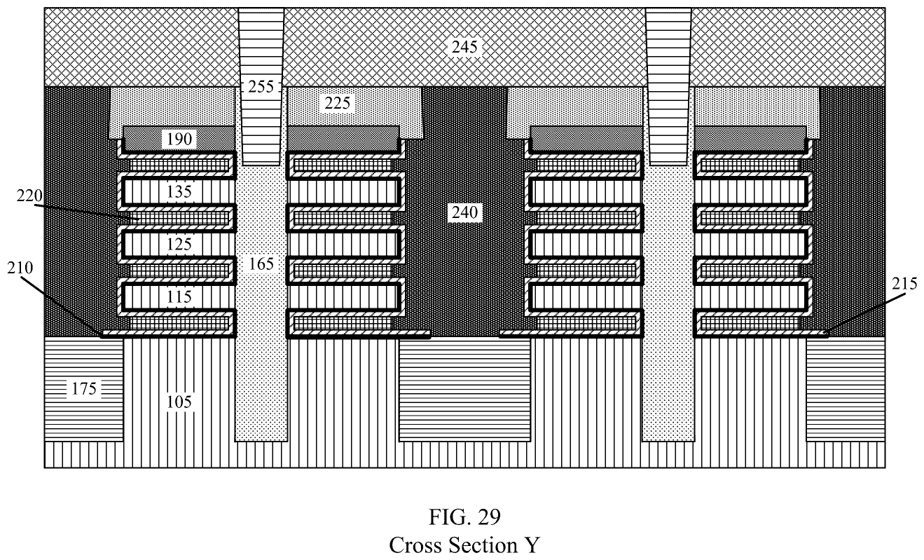

FIGS. 28 and 29 illustrate cross sections X and Y, respectively, of the plurality of nanodevices ND1, ND2, ND3, ND4 after a first option for middle-of-line (MOL) formation, according to the embodiment of the present invention. MOL relates to the set of wafer processing steps used to create the structures that provide the local electrical connections between transistors; mainly gate contact formation; occurs after front-end-of-line (transistors) and before back-end-of-line (wiring) processes. In FIG. 28, MOL ILD 245 is formed directly atop the gate spacer 185, SAC cap 225, and ILD 205. Then, a seventh plurality of trenches (not shown) are formed between each gate spacer 185 and top dielectric bar 190 through the MOL ILD 245 and ILD 205. Then, the seventh plurality of trenches are filled with a conductive metal (e.g., including a silicide liner, such as Ni, Ti, NiPt, an adhesion metal liner, such as TiN and conductive metal fill, such as W, Co, or Ru) to form the plurality of source/drain contacts 250 located directly atop the plurality of source/drains 200. In FIG. 29, the MOL ILD 245 is formed directly atop the dielectric fill 240, SAC cap 225, and the plurality of dielectric bars 165. Then, an eighth plurality of trenches (not shown) are formed through the MOL ILD 245 and a portion of the plurality of dielectric bars 165. Then, the eighth plurality of trenches are filled with a conductive metal to form the plurality of gate contacts 255.

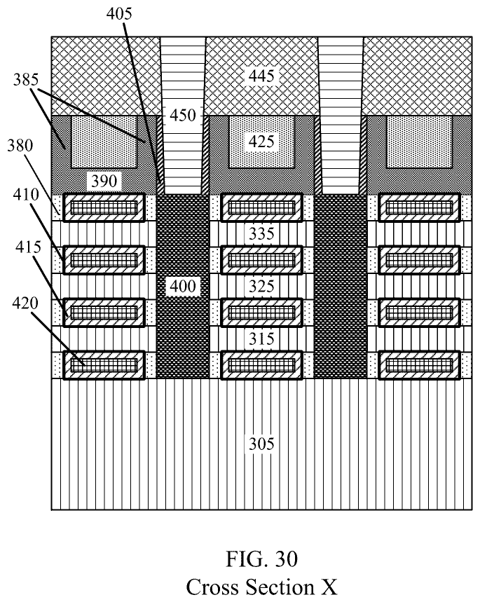

FIGS. 30-35 illustrate cross sections X and Y of the plurality of nanodevices ND1, ND2, ND3, ND4 after substrate 305 formation, nanosheet 315, 325, 335 formation, STI 375 formation, dielectric bar 365 formation, gate spacer 385 and top dielectric bar 390 formation, inner spacer 380 formation, S/D 395 formation, ILD 405 formation, high-k dielectric metal 410 deposition, WFM 415 formation, conductive metal fill 420 formation, SAC cap 425 formation, and dielectric fill 440 deposition, according to the embodiment.

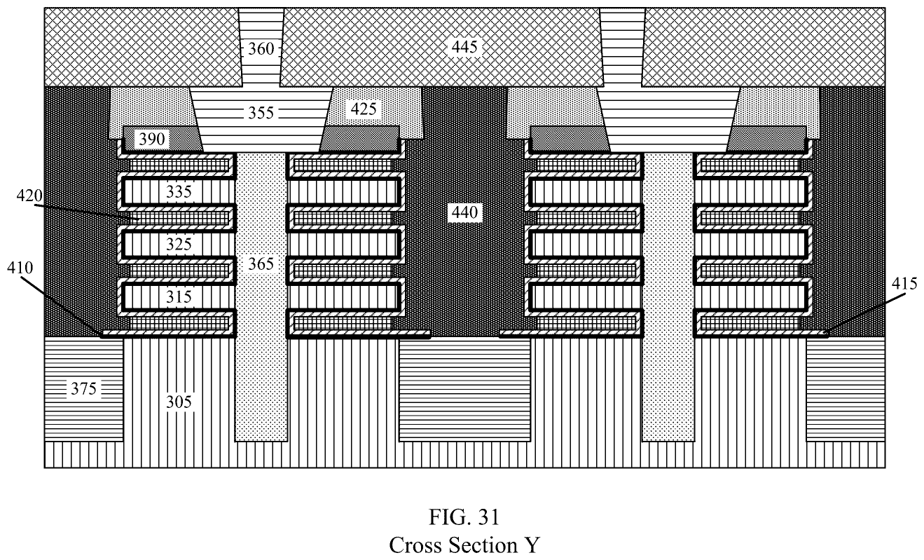

FIGS. 30 and 31 illustrate cross sections X and Y, respectively, of the plurality of nanodevices ND1, ND2, ND3, ND4 after a second option for middle-of-line (MOL) formation, according to the embodiment of the present invention. In one or more aspects of the disclosure, MOL formation is performed with variations. In FIG. 30, MOL ILD 445 is formed directly atop the gate spacer 385, SAC cap 425, and ILD 405. Then, a ninth plurality of trenches (not shown) are formed between each gate spacer 385 and top dielectric bar 390 through the MOL ILD 445 and ILD 405. Then, the ninth plurality of trenches are filled with a conductive metal to form the plurality of source/drain contacts 450. In FIG. 31, a tenth plurality of trenches (not shown) is formed through SAC cap 425, top dielectric bar 390, the high-k dielectric metal 410, and a portion of the plurality of dielectric bars 365. Then, the tenth plurality of trenches are filled with a conductive metal to form the plurality of gate contacts 355 and the plurality of vias 360. Then, the MOL ILD 445 is formed directly atop the dielectric fill 440, SAC cap 425, and the plurality of gate contacts 355. Each of the plurality of gate contacts 355 includes a respective via of the plurality of vias 360.

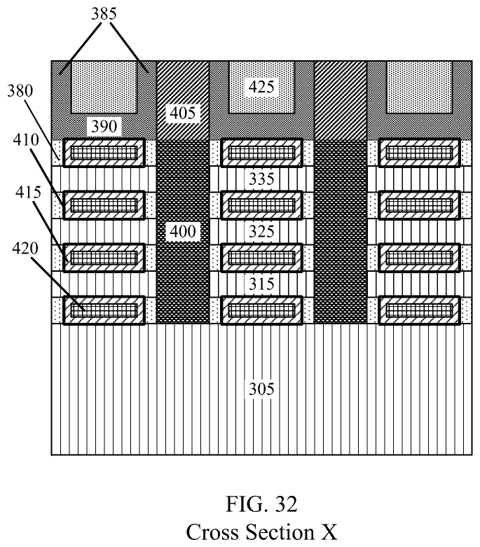

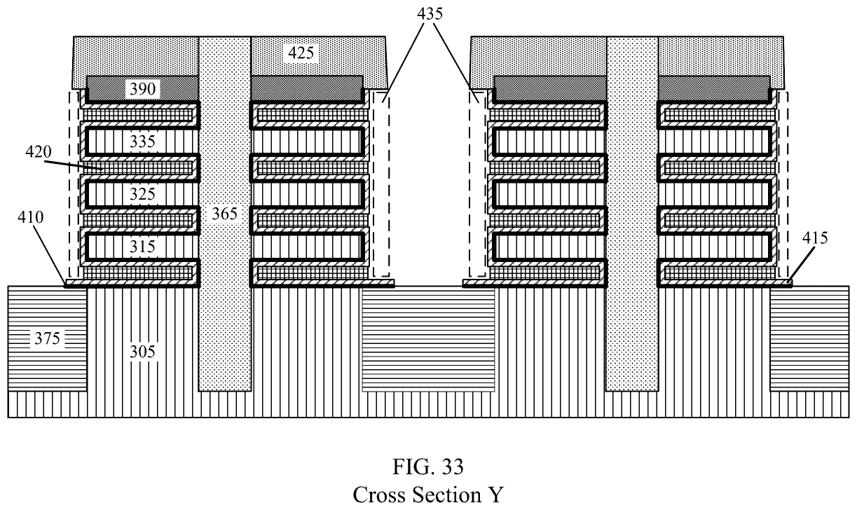

FIGS. 32 and 33 illustrate cross sections X and Y, respectively, of the plurality of nanodevices ND1, ND2, ND3, ND4 after less-selective W recessing, according to the embodiment of the present invention. In one or more aspects of the disclosure, in FIG. 33, the plurality of recesses 435 are formed directly atop the WFM 415 to the backside of the SAC cap 425 and, laterally, through a portion of the conductive metal fill 415 until sidewalls of the WFM 415 are exposed. Then, the plurality of recesses 435 are further extended through a portion of the conductive metal fill 420 a width W4 (not shown) that is less than the width W3 (FIG. 25).

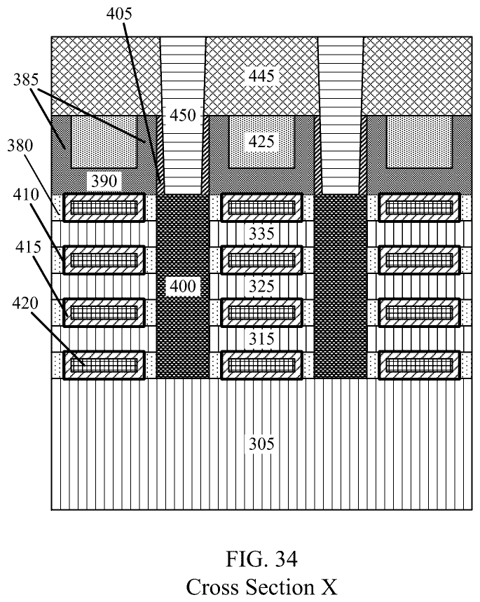

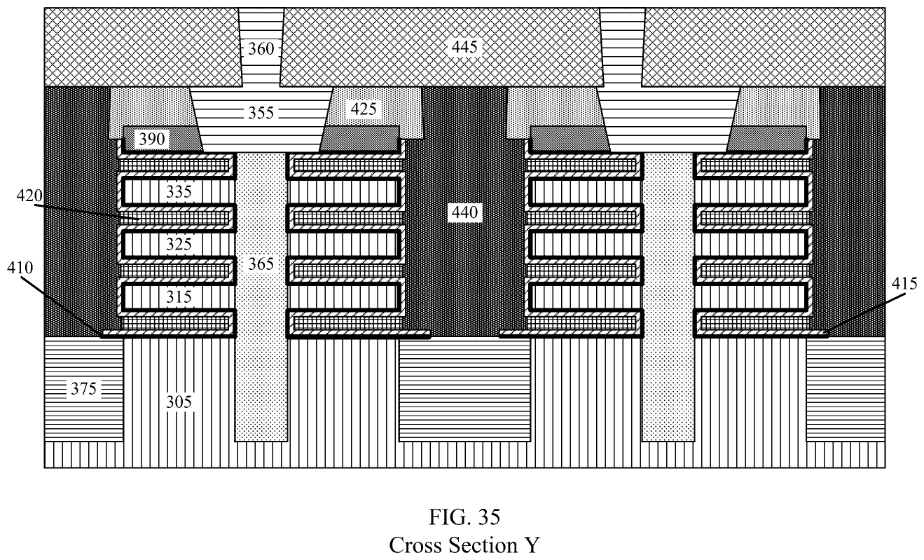

FIGS. 34 and 35 illustrate cross sections X and Y, respectively, of the plurality of nanodevices ND1, ND2, ND3, ND4 after middle-of-line (MOL) formation with less-selective W recessing, according to the embodiment of the present invention. In FIG. 34, MOL ILD 445 is formed directly atop the gate spacer 385, SAC cap 425, and ILD 405. Then, an eleventh plurality of trenches (not shown) are formed between each gate spacer 385 and top dielectric bar 390 through the MOL ILD 445 and ILD 405. Then, the eleventh plurality of trenches are filled with a conductive metal to form the plurality of source/drain contacts 450 located directly atop the plurality of source/drains 400. In FIG. 35, a twelfth plurality of trenches (not shown) is formed through SAC cap 425, top dielectric bar 390, the high-k dielectric metal 410, and a portion of the plurality of dielectric bars 365. Then, the twelfth plurality of trenches are filled with a conductive metal to form the plurality of gate contacts 355. Each gate contact 355 includes a respective via of the plurality of vias 360. A frontside surface of the plurality of gate contacts 355 connects to the respective vias 360. Then, the MOL ILD 445 is formed directly atop the dielectric fill 440, SAC cap 425, and the plurality of source/drain contacts 355.

It may be appreciated that FIGS. 1-35 provide only an illustration of one implementation and do not imply any limitations with regard to how different embodiments may be implemented. Many modifications to the depicted environments may be made based on design and implementation requirements. The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a substrate;
a plurality of nanosheets located parallel to the substrate;
a first dielectric bar extending upwards from the substrate through the plurality of nanosheets, wherein the plurality of nanosheets extend laterally from sidewalls of the first dielectric bar;
a high-k dielectric metal on a frontside surface and a backside surface of each nanosheet in the plurality of nanosheets and on the sidewalls of the first dielectric bar;
a work function metal on a frontside surface, a backside surface, and sidewalls of the high-k dielectric metal; and
a conductive metal fill between one or more portions of the work function metal, wherein the conductive metal fill connects to a sidewall of the work function metal.

2. The semiconductor device of claim 1, wherein the work function metal is comprised of a titanium alloy.

3. The semiconductor device of claim 1, wherein the conductive metal fill is comprised of W, TaN, Ru, Al, and TiAlC.

4. The semiconductor device of claim 1, further comprising:
a second dielectric bar parallel to the plurality of nanosheets.

5. The semiconductor device of claim 4, wherein the high-k dielectric metal is continuous from a sidewall of the second dielectric bar that is connected to a frontside surface of an STI region.

6. The semiconductor device of claim 5, wherein the work function metal is continuous and in contact with the high-k dielectric metal.

7. The semiconductor device of claim 1, further comprising:
a dielectric fill connected to a sidewall of the conductive metal fill.

8. A semiconductor device comprising:
a substrate;
a plurality of nanosheets located parallel to the substrate;
a first dielectric bar extending upwards from the substrate through the plurality of nanosheets, wherein the plurality of nanosheets extend laterally from sidewalls of the first dielectric bar;
a high-k dielectric metal on a frontside surface and a backside surface of each nanosheet in the plurality of nanosheets and on the sidewalls of the first dielectric bar;
a work function metal on a frontside surface, a backside surface, and exposed sidewalls of the high-k dielectric metal;
a conductive metal fill between the work function metal, wherein the conductive metal connects to a sidewall of the work function metal; and
a gate contact in direct contact with a frontside surface of the first dielectric bar.

9. The semiconductor device of claim 8, wherein the work function metal is comprised of a titanium alloy.

10. The semiconductor device of claim 8, wherein the conductive metal fill is comprised of W, TaN, Ru, Al, and TiAlC.

11. The semiconductor device of claim 8, further comprising:
a second dielectric bar parallel to the plurality of nanosheets.

12. The semiconductor device of claim 11, wherein the high-k dielectric metal is continuous from a sidewall of the second dielectric bar that is connected to a frontside surface of an STI region.

13. The semiconductor device of claim 12, wherein the work function metal is continuous and in contact with the high-k dielectric metal.

14. The semiconductor device of claim 8, further comprising:
a dielectric fill connected to a sidewall of the conductive metal fill.

15. A semiconductor device comprising:
a substrate;
a plurality of nanosheets located parallel to the substrate;
a first dielectric bar extending upwards from the substrate through the plurality of nanosheets, wherein the plurality of nanosheets extend laterally from sidewalls of the first dielectric bar;
a high-k dielectric metal on a frontside surface and a backside surface of each nanosheet in the plurality of nanosheets and on the sidewalls of the first dielectric bar;
a work function metal on a frontside surface, a backside surface, and exposed sidewalls of the high-k dielectric metal;
a conductive metal fill between the work function metal, wherein the conductive metal connects to a sidewall of the work function metal;
a gate contact on a frontside surface of the first dielectric bar; and
a via connected to the frontside surface of the gate contact.

16. The semiconductor device of claim 15, wherein the work function metal is comprised of a titanium alloy.

17. The semiconductor device of claim 15, wherein the conductive metal fill is comprised of W, TaN, Ru, Al, and TiAlC.

18. The semiconductor device of claim 15, further comprising:
a second dielectric bar parallel to the plurality of nanosheets.

19. The semiconductor device of claim 18, wherein the high-k dielectric metal is continuous from a sidewall of the second dielectric bar that is connected to a frontside surface of an STI region.

20. The semiconductor device of claim 19, wherein the work function metal is continuous and in contact with the high-k dielectric metal.
